(19) United States
(12) Patent Application Publication
(10) Pub. No.: US 2001/0044077 A1
(43) Pub. Date: Nov. 22, 2001

(54) STABILIZATION OF CHEMICALLY AMPLIFIED RESIST COATING

(76) Inventor: ZOILO CHEN HO TAN, CUPERTINO, CA (US)

Correspondence Address: PATENT COUNSEL, LEGAL AFFAIRS DEPT. APPLIED MATERIALS, INC., P.O. BOX 450A, SANTA CLARA, CA, 95052, US

(21) Appl. No.: 09/293,713

(22) Filed: Apr. 16, 1999

(51) Int. Cl. G03C 5/00; G03F 9/00

(52) U.S. Cl. 430/315; 430/5; 430/313

(57) ABSTRACT

Environmental contamination of chemically amplified resist used in lithography is overcome by use of a coating, such as a thin layer of a charge dissipation material, applied over the fresh CAR layer. This overcoat stabilizes process control and also makes it possible to precoat the CAR on wafer or mask blanks, making them usable even several months after the coating takes place. The overcoating is a conductive material in the electron beam lithography regime, thereby providing charge dissipation during electron beam exposure improving accuracy. The conductive material is, for instance, a liquid organic conductive material at its application, such as PanAquas, or a thin layer of sputtered or evaporated metal.

### FIELD OF INVENTION

This invention relates to lithography and more specifically to lithography using chemically amplified resists.

### BACKGROUND

Lithography is a well known technique, especially in the semiconductor field, and involves coating a substrate which is, e.g., a semiconductor wafer or a reticle substrate with a layer of resist. The resist is sensitive to exposing energy which is typically either ultraviolet light, laser light, X rays or an electron beam. Portions of the resist are exposed and the remainder is not exposed. This is accomplished either by scanning a beam of the light or electrons across the resist to define patterns or, in the case of exposing certain types of wafers, applying the radiation through a partially transmissive mask, thereby to expose only non-masked portions of the resist.

The resist is subsequently developed and the unexposed regions are either removed or remain, with the complementary exposed portions either remaining or being removed depending on whether the resist works in negative tone or positive tone, respectively. Thereby the exposure patterns the resist on the substrate. Subsequent steps typically involve ion implantation or etching or oxide growth so that the resist pattern is transferred into the underlying material. This is either the underlying substrate or, in the case of a mask, a thin layer of, for instance, chromium metal applied between the resist and the substrate which is thereby partially removed to form a mask.

Lithography is thus used for making devices (for instance, either semiconductor devices or micro-machined devices) and for making masks used in photolithography for exposure of other wafers.

There are many well known formulations of resist for both electron beam exposure and light exposure at various wavelengths, as well as X-ray exposure. One category of enhanced sensitivity resists called chemically amplified resist (CAR) has been known for many years. CAR involves, e.g., an acid catalyzation process. Many variations of chemically amplified resists are commercially available primarily for 248 nm and 193 nm deep ultraviolet light lithography application. Many of these CARs have been used in electron beam light lithography. It is known that resists and especially CAR is sensitive to certain environmental contaminants, thus rendering their use for both wafer fabrication and for mask fabrication somewhat problematic and requiring special handling. This includes exposure and development very soon after application. It has been found that CAR deteriorates in terms of lithographic performance as soon as one hour (or less) after its application. Of course this undesirably increases cost. It also has limited use of the otherwise beneficial CAR.

Examples of positive tone CAR are APEX, UVIIHS, UV5, and UV6 manufactured by Shipley Co., Inc., AZDX11000P, DX1200P and DX1300P manufactured by Clariant Corporation, ARCH 8010 and ARCH 8030 manufactured by Arch Chemicals, ODUR-1010 and ODUR-1013 manufactured by Tokyo Ohka Kogyo Co., Ltd. and PEK110A5 manufactured by Sumitomo Chemicals, Inc. Examples of negative tone CAR are SAL-601, SAL-603 manufactured by Shipley Co., Inc., EN-009 PE manufactured by Tokyo Ohka Kogyo Co., Ltd., and NEB 22 manufactured by Sumitomo Chemicals, Inc.

Therefore, it would be desirable to improve the usability and storability of chemically amplified resist applied on a substrate by finding ways to reduce the undesirable effects thereon of environmental contaminants.

### SUMMARY

In accordance with this invention, the environmental sensitivity of resist is eliminated, or at least substantially reduced, by overcoating a chemically amplified (or other) resist with a thin coating of a protective but transmissive material. This allows long term storage (e.g., up to four months or longer) of unexposed resist applied to a substrate. The coating in some embodiments is an electric charge dissipation (conductive) material. Although non-conductive material can also be used, it is advantageous, particularly in electron beam exposure, to use a conductive overcoat. The coating provides two desirable functions. These are, first, charge dissipation during electron beam exposure for accurate overlay of two successive layers in multilevel mask making, and, second, maintaining the shelf life and therefore stability of lithographic performance (in terms of critical dimension and integrity) of the resist, e.g., for a day, a week, a month, or months (at least four months as determined by experiment) after its application. Shelf life is not limited to mere storage, but includes, e.g., time spent in transit. This is a substantial improvement, since as stated above normally CAR formulations are subject to undesirable performance changes within minutes of application. Thus such an unexposed coated substrate (wafer or reticle) becomes an article of manufacture and of commerce rather than merely a transitory result of a process. This opens up a new business/manufacturing opportunity of commerce (inter- or intra-company) in such articles of manufacture, not available heretofore.

Thus desirably such overcoated resist can be prepared on the substrate (wafer or reticle) months before its actual exposure, in contrast to present use of CAR which requires application immediately prior to the exposure. Of course, this means that one company (or location) can manufacture the resist coated wafers or reticle blanks, and another company (or location) can then later perform the exposure, in contrast to present practice. The charge dissipation coating material is any suitable conductive material which can be readily applied, for instance, a thin layer of an initially liquid organic conductive material (which dries) such as polyaniline, or a thin layer of a metal such as chromium or aluminum suitably applied.

The exposing electron beam typically is operated at or greater than 10,000 volts accelerating voltage and therefore can have a penetration range (through the coating material) on the order of about one micron to several microns below the resist surface. In the case of light exposure, the metal conductive coating layer will not be applicable.

### BRIEF DESCRIPTION OF THE DRAWINGS

FIG. 1 shows a mask blank with applied layers of CAR and charge dissipation material being exposed to a beam of exposing radiation in accordance with this invention.

### DETAILED DESCRIPTION

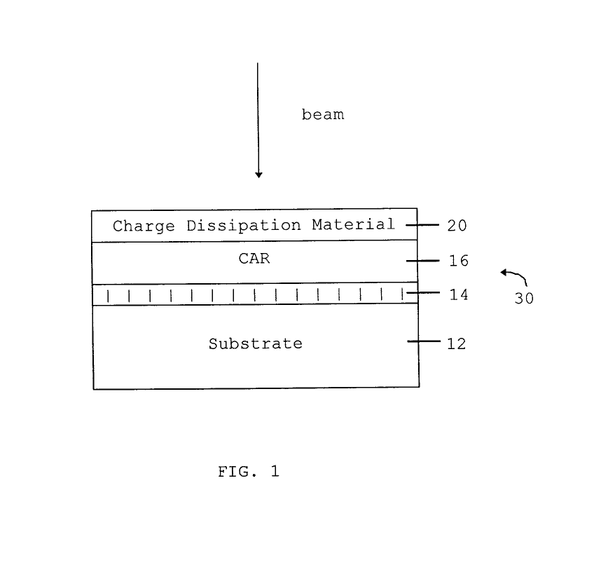

The result of the above-described process of applying a layer of protective material over a CAR layer is illustrated in FIG. 1 which shows a conventional substrate 12 which, for instance, is the quartz or glass substrate (blank) used for making masks on which is conventionally a thin layer of metal such as chromium 14, which is the mask layer to be patterned. Overlying these is the CAR layer 16 applied to a conventional thickness dependent on factors such as the CAR formulation and exposure technique. Structures 12, 14 and 16 are wholly conventional. An additional layer 20 is applied over the CAR layer 16. Layer 20 is in some embodiments of a charge dissipation material. This material is applied subsequent to application of the CAR layer 16 and while the CAR layer is fresh (before it is subject to environmental contamination). Then, later, structure 30 is exposed to actinic radiation, for instance a scanning electron beam or actinic (exposing) light in a conventional lithographic machine. In any case, the CAR is a formulation selected to be sensitive to the particular exposing radiation. Note that while a beam of exposing radiation is depicted here, this is not required. In lithography using a mask to expose a semiconductor wafer, the exposing radiation is not a focused beam.

In the case of a semiconductor wafer, the chromium layer 14 is not present on the substrate 12, which then would typically be crystalline silicon. However, in other respects use of the coating material layer 20 is the same in both the case of fabricating wafers and making a mask as depicted in FIG. 1. As described above, advantageously the protective layer 20 also provides electric charge dissipation during an electron beam exposure, since the electrons are dissipated through layer 20 rather than building up on the otherwise exposed upper surface of CAR layer 16. (Resists are generally electrically insulative.) This charge dissipation has been found to be beneficial for accurate overlay when one is forming a mask with two successive layers in multilevel mask making, as in the fabrication of phase shift masks where some chromium is removed in the image areas, thereby rendering it nonconductive when the second level is exposed. (See Tan publication referenced below.)

The protective layer is transmissive of the exposing radiation. A thin metal coating layer (typically 100-200 Å thick) is transmissive of an electron beam. If the actinic exposure is other than an electron beam, the overcoat material is chosen so that it is transmissive to the wavelength of exposure, such as 248 nm or 193 nm deep ultraviolet light.

Also, whether the exposing radiation beam is light or electrons, the presence of the protective layer improves the shelf life of the underlying CAR layer by shielding the CAR layer from environmental contaminants (including air and moisture). The coating layer 20 of course in any case is transmissive to the incident radiation.

The following describes fabrication of the structure 30 of FIG. 1 and its use. The formation of chromium layer 14 on substrate 12 is conventional, as is the subsequent overlay of the CAR layer 16. To the freshly prepared CAR layer 16 (which has typically been conventionally soft baked), a thin coating of a charge dissipation material 20 is applied. Examples of application of charge dissipation material are first spin coating a thin (800 to 2000 Å) layer of liquid organic conductive material (water-soluble conductive polymer), such as a polyaniline, commercially available as PanAquas (from IBM Corp) or Aquasave (from Nitto Chemicals). See “Conducting polyanilines: Discharge layers for electron-beam lithography”, Marie Angelopoulos et al., J. VAC. SCI. TECHNOL. B 7(6), (Nov/Dec 1989), pp. 1519-1523, incorporated herein by reference in its entirety. Such water-soluble materials can be removed (after exposure of the resist) by rinsing in distilled water. Such a film has a conductivity of −0.1/ohm-cm.

Alternatively, the charge dissipation coating is a thin metal layer 20 formed by evaporating or sputtering, for instance, to a thickness of 100 to 200 Å. Examples of suitable metals are chromium and aluminum. The coating material is selected to have no chemical effect on the resist. For further detail on an example of application of charge dissipation material on resist, see “Application of charge dissipation material on MEBES® phase shift mask fabrication”, Zoilo C. H. Tan et al., SPIE Vol. 2322 Photomask Technology and Management (1994), pp. 141-148, incorporated herein by reference in its entirety.

Structure 30 is conventionally exposed (some time—minutes to months—later) using the electron beam or actinic light as in FIG. 1. A subsequent post exposure bake is also conventional.

Then the upper layer 20 is stripped, e.g., by rinsing in deionized water which removes the organic conductive material. Another example, if the layer 20 is chromium, is stripping with a suitable acidic etching fluid. If layer 20 is aluminum, it similarly is removed by etching with alkaline etchant.

Next is development of the exposed CAR layer 16. This is conventional using whatever developer technique is suitable for the particular CAR formulation. If the development is performed using an alkaline developer formulation, this may by itself also remove the layer 20, if layer 20 is aluminum. In other words, the application of the alkaline developer to structure 30 would initially dissolve the protective layer 20 and then perform the actual development of the underlying CAR layer 16. This process therefore is exposure, bake, remove layer 20, develop resist. Alternately, after exposure to actinic radiation, the upper layer 20 is stripped as described above, to be followed with post exposure bake and development of the underlying CAR layer 16 (expose, remove, bake, develop).

This disclosure is illustrative and not limiting. The particular materials disclosed and the parameters of their use are also illustrative and not limiting; one of ordinary skill in the field will appreciate that various substitutions and modifications can be made. In any case, such modifications or substitutions are intended to fall within the scope of the appended claims.

I claim:

1. An article of manufacture which is a reticle blank suitable for storage and subsequent lithographic exposure, comprising:
a substrate;
a layer of non-transmissive material over the substrate;
a layer of unexposed chemically amplified resist over the non-transmissive layer; and
a layer of protective material over the layer of resist.

2. The reticle of claim 1, wherein the protective material is a charge dissipation material.

3. The reticle of claim 2 where the charge dissipation material is one of a metal or an organic conductive material.

4. The reticle of claim 3, where the organic conductive material is a polyaniline.

5. The reticle of claim 1, wherein the reticle is storable for at least one day prior to exposure of the resist.

6. An article of manufacture suitable for storage and subsequent lithographic exposure, comprising:
a substrate;
a layer of chemically amplified resist over the substrate; and
a layer of protective material over the resist layer.

7. The article of claim 6, wherein the protective material is a charge dissipation material.

8. The article of claim 7, where the charge dissipation material is one of a metal or an organic conductive material.

9. The article of claim 8, where the organic conductive material is a polyaniline.

10. The article of manufacture of claim 6, wherein the article is storable for at least one day prior to exposure of the resist.

11. A method of preparing a substrate for storage and subsequent lithographic exposure, comprising the acts of:
forming a layer of chemically amplified resist over a principal surface of the substrate;
forming a layer of protective material over the resist layer; and
exposing the resist to actinic radiation at least one hour after the act of forming.

12. The method of claim 11, wherein the protective material is a charge dissipation material.

13. The method of claim 12, where the charge dissipation material is one of a metal or an organic conductive material.

14. The method of claim 13, where the organic conductive material is a polyaniline.

15. The method of claim 11, wherein the substrate is transmissive of exposing energy and wherein there is a layer of material non-transmissive of the exposing energy over the substrate and under the resist layer.

16. The method of claim 11, wherein the act of forming comprises one of the acts of spin coating, evaporating, or sputtering.

17. The method of claim 11, further comprising the act of:
baking the resist layer prior to the act of forming the layer of protective material.

18. A method of preparing, storing and lithographically exposing a substrate, comprising the acts of:
forming a layer of chemically amplified resist over a principal surface of the substrate;
forming a layer of protective material over the resist layer;
storing the substrate with the protective material and resist layer for at least one day;
after the storage, exposing the substrate to exposing energy, thereby exposing selected portions of the resist through the layer of protective material;
removing at least part of the layer of protective material; and
developing the exposed resist after the act of removing.

19. The method of claim 18, where the protective material is a charge dissipation material.

20. The method of claim 19, where the charge dissipation material is one of a metal or an organic conductive material.

21. The method of claim 20, where the organic conductive material is a polyaniline.

22. The method of claim 18, wherein the act of forming comprises one of the acts of spin coating, evaporating, or spattering.

23. The method of claim 18, further comprising the act of:
baking the resist layer prior to forming the layer of protective material.

24. The method of claim 18, wherein the substrate is transmissive of exposing energy and wherein there is a layer of material non-transmissive of the exposing energy over the substrate and under the resist layer.

25. The method of claim 18, wherein the act of removing comprises one of the acts of rinsing and etching.

26. The method of claim 18, wherein the act of removing precedes the act of developing.

27. The method of claim 18, wherein the act of removing takes place at the same time as the act of developing.

28. The method of claim 18, wherein the act of storing has a duration of at least one week.

29. The method of claim 18, wherein the act of storing has a duration of at least one month.
